(19) United States
(12) Patent Application Publication
(10) Pub. No.: US 2025/0228074 A1
(43) Pub. Date: Jul. 10, 2025

(54) DISPLAY PANEL AND STRETCHABLE DISPLAY PANEL, METHOD FOR MANUFACTURING SAME, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Kening ZHENG, Beijing (CN); Dengyu WANG, Beijing (CN); Changlong YUAN, Beijing (CN); Zhenhua ZHANG, Beijing (CN); Tong WU, Beijing (CN)

(21) Appl. No.: 18/834,519

(22) PCT Filed: Sep. 26, 2023
(86) PCT No.: PCT/CN2023/121702

§ 371 Date: Jul. 30, 2024

(30) Foreign Application Priority Data
Nov. 30, 2022 (CN) 202211530057.3

(51) Int. Cl. H10K 59/122; H10K 59/12; H10K 59/80

(52) U.S. Cl. CPC H10K 59/122; H10K 59/1201; H10K 59/873

(57) ABSTRACT

Provided is display panel. The display panel includes a flexible substrate, a first pixel definition layer, a plurality of first pixel structures, a plurality of first cathode layers, and a plurality of first pixel encapsulation layers; wherein the first pixel definition layer is attached to the flexible substrate and a plurality of first pixel openings are defined in the first pixel definition layer; the first pixel structures are respectively is disposed in the first pixel opening and attached to the flexible substrate; each of the plurality of first cathode layers is disposed in each of the plurality of first pixel openings and attached to each of the plurality of first pixel structures; and each of the plurality of first pixel encapsulation layers is disposed outside each of the plurality of first cathode layers at each of the plurality of first pixel openings and seals the first pixel opening.

### CROSS-REFERENCE TO RELATED APPLICATION

This application is a U.S. national phase application based on PCT/CN2023/121702, filed on Sep. 26, 2023, which claims priority to Chinese patent Application No. 202211530057.3, filed on Nov. 30, 2022 and entitled “DISPLAY PANEL AND STRETCHABLE DISPLAY PANEL, METHOD FOR MANUFACTURING SAME, AND DISPLAY DEVICE”, the contents of which are incorporated herein by reference in their entireties.

### TECHNICAL FIELD

The present disclosure related the field of display technology, and in particular, relates to a display panel and a stretchable display panel, methods for manufacturing the same, and a display device.

### BACKGROUND

With the rapid development in the information age, the organic light-emitting diode (OLED) display technology has gradually become indispensable because of its advantages of self-illumination, wide viewing angle, thinness and lightweight, low energy consumption, and bendability, or the like. The stretchable OLED better accommodates user requirements.

### SUMMARY

Embodiments of the present disclosure provide a display panel and a stretchable display panel, methods for manufacturing the same, and a display device.

According to some embodiments of the present disclosure, a display panel is provided. The display panel includes a flexible substrate, a first pixel definition layer, a plurality of first pixel structures, a plurality of first cathode layers and a plurality of first pixel encapsulation layers;
wherein the first pixel definition layer is attached to the flexible substrate and the first pixel definition layer has a plurality of first pixel openings;
the plurality of first pixel structures are respectively disposed in the plurality of first pixel openings and attached to the flexible substrate;
the first cathode layers are disposed in the first pixel openings and attached to the first pixel structures; and
the first pixel encapsulation layer is disposed outside the first cathode layer at the first pixel opening and seals the first pixel opening.

In some embodiments, the display panel further includes a first CPM layer;
wherein the first CPM layer is disposed on a side, away from the flexible substrate, of the first pixel definition layer and attached to the first pixel definition layer; and
a plurality of first cathode openings are arranged in the first CPM layer, wherein the plurality of first cathode openings correspond to the plurality of first pixel structures in terms of position.

In some embodiments, an orthographic projection of the first CPM layer is not overlapped with an orthographic projection of the first cathode layer along a thickness direction of the flexible substrate.

In some embodiments, an angle between an inner side wall of the first pixel opening and a side, close to the flexible substrate, of the first pixel definition layer is less than a first predetermined angle threshold.

In some embodiments, a thickness of the first pixel definition layer is greater than a first predetermined thickness threshold.

In one possible implementation, a plurality of first annular partition grooves are disposed in a side, away from the flexible substrate, of the first pixel definition layer, wherein the first annular partition grooves surround an outer side of the first pixel opening.

In some embodiments, the first CPM layer is a transparent CPM layer.

In some embodiments, the first CPM layer is an Ultraviolet (UV) resistant transparent CPM layer.

In some embodiments, a plurality of first arcuate grooves are disposed in a side, away from the flexible substrate, of the first pixel definition layer; and
the first CPM layer is attached to bottoms of the plurality of first arcuate grooves.

According to some embodiments of the present disclosure, a stretchable display panel is provided. The stretchable display panel includes a substrate, a second pixel definition layer, a plurality of second pixel structures, a plurality of second cathode layers and a plurality of second pixel encapsulation layers; wherein
the substrate includes a plurality of pixel islands and a plurality of line bridges, wherein each of the plurality of the pixel islands is connected to adjacent two of the plurality of line bridges;
the second pixel definition layer is attached to the substrate, and a plurality of second pixel openings (221) are defined in the second pixel definition layer, wherein each of the plurality of second pixel openings corresponds each of the plurality of pixel islands in terms of position;
the plurality of second pixel structures are respectively disposed in the plurality of second pixel openings and attached to the pixel island;
each of the plurality of second cathode layers is disposed in each of the plurality of second pixel openings and attached to each of the plurality of second pixel structures; and
each of the plurality of second pixel encapsulation layers is disposed outside each of the plurality of second cathode layers at each of the plurality of second pixel openings and seals the second pixel opening.

In some embodiments, the stretchable display panel further includes a second CPM layer; wherein
the second CPM layer is disposed on a side, away from the substrate, of the second pixel definition layer and attached to the second pixel definition layer; and
a plurality of second cathode openings (261) are defined in the second CPM layer, wherein each of the plurality of second cathode openings corresponds to each of the plurality of second pixel structures in terms of position.

In some embodiments, an orthographic projection of the second CPM layer is not overlapped with an orthographic projection of each of the plurality of second cathode layers along a thickness direction of the substrate.

In some embodiments, an angle between an inner side wall of the second pixel opening and a side, close to the substrate, of the second pixel definition layer is less than a first predetermined angle threshold.

In some embodiments, a thickness of the second pixel definition layer is greater than a second predetermined thickness threshold.

In some embodiments, a plurality of second annular partition grooves are disposed in a side, away from the substrate, of the second pixel definition layer, wherein the second annular partition grooves surround an outer side of the second pixel opening.

In some embodiments, the second CPM layer is a transparent CPM layer.

In some embodiments, the second CPM layer is a UV resistant transparent CPM layer.

In some embodiments, a plurality of second arcuate grooves are defined in a side, away from the substrate, of the second pixel definition layer; and
the second CPM layer is attached to bottoms of the second arcuate grooves.

According to some embodiments of the present disclosure, a method for manufacturing a display panel is provided, wherein the method is applicable to the display panel as described in any one of the above embodiments, and the method includes:
connecting the first pixel definition layer to the flexible substrate, and evaporation depositing the first pixel structure into the first pixel opening;
alternating a plurality of vias on a mask plate with the plurality of first pixel structures, and connecting the mask plate to a side, away from the flexible substrate, of the first pixel definition layer;
forming the first CPM layer on a side, away from the flexible substrate, of the first pixel definition layer by evaporation depositing a CPM material;
separating the mask plate from the first pixel definition layer;
forming the first cathode layer on a side, away from the flexible substrate, of the first pixel structure by evaporation depositing a cathode material; and
forming the first pixel encapsulation layer outside the first cathode layer at the first pixel opening by evaporation depositing the encapsulation material.

According to some embodiments of the present disclosure, a method for manufacturing a display panel is provided, wherein the method is applicable to the stretchable display panel as described in any one of the above embodiments, and the method includes:
providing a substrate including the plurality of pixel islands and the plurality of line bridges;
arranging the plurality of the second pixel openings opposite to the plurality of pixel islands, connecting the second pixel definition layer to the substrate, and evaporation depositing the second pixel structure into the second pixel opening;
alternating a plurality of vias on a mask plate with the plurality of second pixel structures, and connecting the mask plate to a side, away from the substrate, of the second pixel definition layer;
forming the second CPM layer on the side, away from the substrate, of the second pixel definition layer by evaporation depositing a CPM material;
separating the mask plate from the second pixel definition layer;
forming the second cathode layer on a side, away from the substrate, of the second pixel structure by evaporation depositing the cathode material; and
forming the second pixel encapsulation layer outside the second cathode layer at the second pixel opening by evaporation depositing the encapsulation material.

According to some embodiments of the present disclosure a display device is provided. The display device includes the display panel or the stretchable display panel as described in any one of the above embodiments.

### BRIEF DESCRIPTION OF DRAWINGS

In order to more clearly illustrate the technical solutions in the embodiments of the present application, the accompanying drawings in the description of the embodiments are briefly introduced below, and it is obvious that the accompanying drawings in the following description are only some of the embodiments of the present application, and other accompanying drawings can be acquired according to these drawings for those of ordinary skill in the art without creative labor.

FIG. 1 is a schematic structural diagram of a display panel according to some embodiments of the present disclosure;

FIG. 2 is a schematic structural diagram of a display panel according to some embodiments of the present disclosure;

FIG. 3 is a schematic top view structural diagram of a first CPM layer and a first cathode layer according to some embodiments of the present disclosure;

FIG. 4 is a schematic diagram of a method for manufacturing a display panel according to some embodiments of the present disclosure;

FIG. 5 is a schematic diagram of a method for manufacturing a display panel according to some embodiments of the present disclosure;

FIG. 6 is a schematic structural diagram of a display panel according to some embodiments of the present disclosure;

FIG. 7 is a schematic top view structural diagram of a first CPM layer, a first cathode layer, and a first pixel definition layer according to some embodiments of the present disclosure;

FIG. 8 is a schematic structural diagram of a display panel according to some embodiments of the present disclosure;

FIG. 9 is a flowchart of a method for manufacturing a display panel according to some embodiments of the present disclosure;

FIG. 10 is a schematic structural diagram of a stretchable display panel according to some embodiments of the present disclosure;

FIG. 11 is a schematic structural diagram of a stretchable display panel according to some embodiments of the present disclosure;

FIG. 12 is a schematic top view structural diagram of a second CPM layer and a second cathode layer according to some embodiments of the present disclosure;

FIG. 13 is a schematic structural diagram of a stretchable display panel according to some embodiments of the present disclosure;

FIG. 14 is a schematic top view structural diagram of a second CPM layer, a second cathode layer, and a second pixel definition layer according to some embodiments of the present disclosure;

FIG. 15 is a schematic structural diagram of a stretchable display panel according to some embodiments of the present disclosure; and

FIG. 16 is a flowchart of a method for manufacturing a stretchable display panel according to some embodiments of the present disclosure.

### DETAILED DESCRIPTION

In order to make the objects, technical solutions and advantages of the present application clearer, the embodiments of the present application are described in further detail below in conjunction with the accompanying drawings.

FIG. 1 is a schematic structural diagram of a display panel according to some embodiments of the present disclosure. Referring to FIG. 1, it can be seen that the display panel includes a flexible substrate 11, a first pixel definition layer 12, a plurality of first pixel structures 13, a plurality of first cathode layers 14, and a plurality of first pixel encapsulation layers 15.

The flexible substrate 11 is mainly configured to support the first pixel structures 13, and its material is plastic or the like.

The first pixel definition layer 12 is attached to the flexible substrate 11 and the two are stacked. The first pixel definition layer 12 is configured to partition the plurality of first pixel structures 13 on the flexible substrate 11 in terms of positon, and a plurality of first pixel openings 121 are defined in the first pixel definition layer 12. The plurality of first pixel openings 121 are uniformly distributed on the first pixel definition layer 12, and have a shape of a rectangle, a rhombus, etc., which is not limited in the embodiments of the present disclosure.

The plurality of first pixel structures 13 are respectively disposed within the plurality of first pixel openings 121 and attached to the flexible substrate 11. The first cathode layer 14 is disposed within the first pixel opening 121, on a side, away from the first pixel definition layer 12, of the first pixel structure 13 and attached to the first pixel structure 13. Each of the first pixel structures 13 is positioned opposite and attached to a first cathode layer 14. By applying pressure at both ends of the first pixel structures 13 and the first cathode layer 14, the first pixel structures 13 are caused to emit light, such that the display panel displays an image.

There are various methods for realizing the plurality of first cathode layers 14. Exemplarily, cathode patterning can be realized by cathode pattern material (CPM), cathode patterning can be realized by laser etching, or other possible methods, which are not limited in the embodiments of the present disclosure.

The material of the first cathode layer 14 is a metal material or a synthetic metal material. For example, it may be indium tin oxide (ITO), magnesium silver alloy (MgAg), argentum (Ag), aluminum (Al), magnesium (Mg), and the like, which is not limited in the embodiments of the present disclosure.

The first pixel encapsulation layer 15 is disposed at the first pixel opening 121, outside of the first cathode layer 14, and seals the first pixel opening 121. Each of the first pixel encapsulation layers 15 encapsulates one first pixel structure 13 and a corresponding first cathode layer 14.

In this way, a corresponding first cathode layer 14 is provided for each first pixel structure 13, thereby facilitating the realization of pixel-level encapsulation of the display panel, avoiding the occurrence of encapsulation failure caused by the use of undercut structures, and improving the stability of the encapsulation.

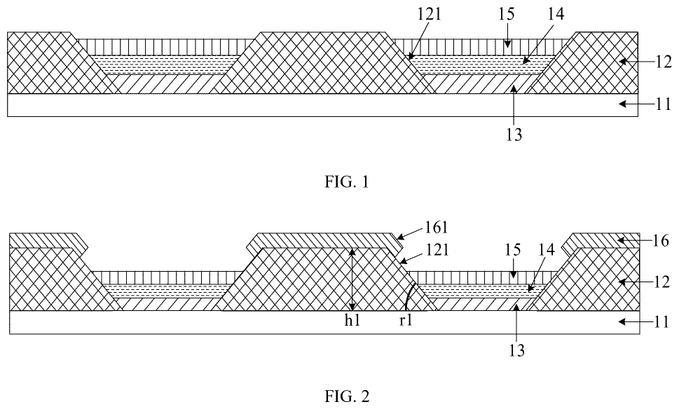

In one possible implementation, the patterning of the plurality of first cathode layers 14 can be achieved by CPM, refereeing to FIG. 2, and the structural arrangement can be as follows.

The display panel further includes a first CPM layer 16, and the first CPM layer 16 is disposed on a side, away from the flexible substrate 11, of the first pixel definition layer 12 and attached to the first pixel definition layer 12. The first CPM layer 16 has a plurality of first cathode openings 161, and the first cathode openings 161 correspond to the first pixel structure 13 in terms of position. The first CPM layer 16 is used for a cathode patterning process to acquire a plurality of first cathode layers 14, and the position of each of the first cathode layers 14 is opposite to the position of one of the first pixel structures 13.

The material of the first CPM layer 16 is a high-fluorine-containing compound, which is less compatible with the cathode material.

In preparing the display panel by the CPM material, the first pixel definition layer 12 needs to be connected to one side of the flexible substrate 11, and then a plurality of first pixel structures 13 need to be disposed within the plurality of first pixel openings 121 of the first pixel definition layer 12 and connected to the flexible substrate 11, and then, the first CPM layer 16 needs to be evaporation deposited on the side, away from the flexible substrate 11, of the first pixel definition layer 12. The formed first CPM layer 16 has a plurality of first cathode openings 161, and the positions of the plurality of first cathode openings 161 correspond to the positions of the first pixel structure 13, such that the regions in the first pixel definition layer 12 other than the first pixel structure 13 can be provided with CPM material.

In the case that the first CPM layer 16 is formed, the cathode material is evaporation deposited on a side, away from the first pixel definition layer 12, of the first CPM layer 16. Because of the poor compatibility between the cathode material and the CPM material, it is difficult for the cathode material to be attached to the CPM material, and the cathode material is attached, through a plurality of the first cathode openings 161 on the first CPM layer 16, to the first pixel structures 13 corresponding to the first pixel structures 13 in terms of position, such that each of the first pixel structures 13 is attached to a corresponding first cathode layer 14.

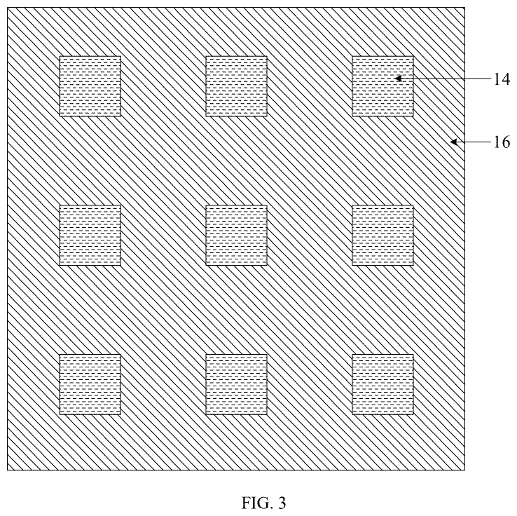

In this way, the display panel can be formed as shown in FIG. 3. FIG. 3 is a schematic top view structural diagram of the first CPM layer 16 and the plurality of first cathode layers 14. In conjunction with FIGS. 2 and 3, it can be seen that, in the display panel, the first cathode layer 14 is provided only at a position opposite to the first pixel structure 13, and the CPM material is provided at other positions, and such a structure facilitates pixel-level encapsulation and improves the reliability of the display panel encapsulation.

In one possible implementation, in the display panel according to the embodiments of the present disclosure, the orthographic projection of the first CPM layer 16 is not overlapped with the orthographic projection of the first cathode layer 14 along the thickness direction of the flexible substrate 11.

In this way, a reasonable space can be allocated for each of the first CPM layer 16 and the plurality of first cathode layers 14, such that the occurrence of the problem that the first CPM layer 16 occupies too much region and causes the first cathode layer 14 to occupy too little region is avoided, and the occurrence of the problem that the first CPM layer 16 occupies too little region and causes the first cathode layer 14 to occupy too much region is also avoided.

Too much or too little region occupied by the first CPM layer 16 reduces the reliability of the encapsulation. In the case that the first CPM layer 16 occupies too much region and the first cathode layer 14 occupies too little area, the display effect of the display panel is worse. Therefore, the structural arrangement that the first CPM layer 16 is not overlapped with the first cathode layer 14 in the embodiments of the present disclosure improves the display effect of the display panel and improve the reliability of the pixel-level encapsulation of the display panel.

In one possible implementation, the shape of the first pixel opening 121 is a square prism shape. That is, the angle (e.g., the angle r1 in FIG. 2) between the inner side wall of the first pixel opening 121 and the side, close to the flexible substrate 11, of the first pixel definition layer 12 is less than 90 degrees, and, correspondingly, the angle between the inner side wall of the first pixel opening 121 and the side, away from the flexible substrate 11, of the first pixel definition layer 12 is greater than 90 degrees. In this way, each inner side wall of the first pixel opening 121 forms a sloped surface, which facilitates the climbing of the layer structure and reduces the risk of breakage of the layer structure in the case that the first pixel structure 13 and the first cathode layer 14 are evaporation deposited.

In one possible implementation, in the embodiments of the present disclosure, in order to avoid the occurrence of the problem that the first CPM layer 16 occupies too much region and the first cathode layer 14 occupies too little region, and in order to realize a structure in which the first CPM layer 16 is not overlapped with the first cathode layer 14, the first pixel definition layer 12 is arranged in the following manner: the angle (e.g., the angle r1 in FIG. 2) between the inner side wall of the first pixel opening 121 and the side, close to the flexible substrate 11, of the first pixel definition layer 12 is less than a first predetermined angle threshold, and the first predetermined angle threshold can be less than 90 degrees.

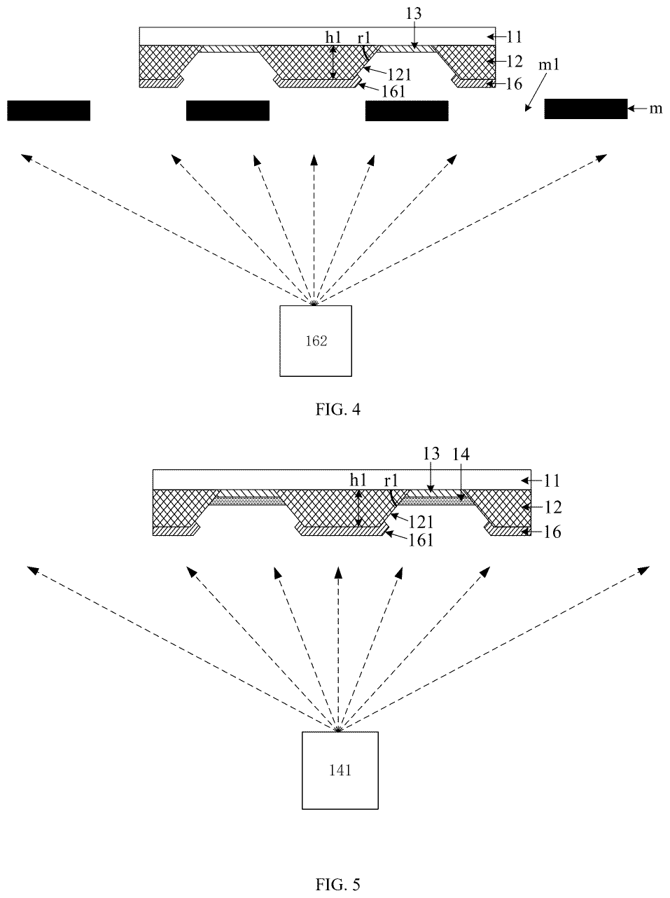

Referring to FIG. 4, in the process of preparing the display panel, prior to evaporation depositing the CPM material 162, it is necessary to install the mask plate m on the side, away from the flexible substrate 11, of the first pixel definition layer 12, and connect the mask plate m to the first pixel definition layer 12 by magnet. The mask plate m has a plurality of vias m1, and it is necessary to alternate the plurality of vias m1 with the plurality of first pixel openings 121. That is, in the thickness direction along the flexible substrate 11, the orthographic projections of the vias m1 is not overlapped with the orthographic projections of the first pixel openings 121. In the case that the mask plate m is installed, the CPM material 162 can be evaporation deposited to pass through the vias m1 to form the first CPM layer 16 with the first cathode openings 161 at the first pixel definition layer 12 corresponding to the vias m1 in terms of position.

Then, referring to FIG. 5, the cathode material 141 is evaporation deposited, and the cathode material 141 cannot be attached to the first CPM layer 16. The evaporation deposited cathode material is partitioned by the first CPM layer 16 into a plurality of unconnected first cathode layers 14 that are each connected to a first pixel structure 13.

During the above manufacturing process, due to a structure such as a magnet is between the mask plate m and the first pixel definition layer 12, a gap inevitably exists between the mask plate m and the first pixel definition layer 12. Due to the gap, the CPM material forms a circle of shadow during the evaporation deposition process, that is, a circle of CPM larger than the outer side of the via m1 is formed due to the gap, and the circle of shadow increases the region occupied by the first CPM layer 16.

In order to avoid the occurrence of the above problem that the first CPM layer 16 increases due to the shadow and thus occupies the region of the first cathode layer 14, the angle r1 is set to be smaller than a first preset angle threshold, and the length and area of the inner side wall of the first pixel opening 121 is increased, such that the shadow is formed at a position, away from the first pixel structure 13, of the inner side wall of the first pixel opening 121, and the first CPM layer 16 does not occupy the position occupied by the first cathode layer 14, ensuring a reasonable region arrangement of the first cathode layer 14, and the first cathode layer 14 is fully contacted with the first pixel structure 13, which improves the display effect of the display panel and improves the reliability of encapsulation.

In some embodiments of the present disclosure, the first predetermined angle threshold is 60 degrees, and, the first predetermined angle can be set based on the actual situation of the display panel. In the case that the region occupied by the first CPM layer 16 is too large, the angle r1 can be appropriately reduced, such that the length and area of the inner sidewall of the first pixel opening 121 are increased, and the range of the region occupied by the first CPM layer 16 is reduced.

In one possible implementation, in the case that the adjustment of the angle r1 cannot satisfy the requirement of the region occupied by the first CPM layer 16, the following arrangement can also be made on the premise of the above arrangement of the angle r1. The thickness of the first pixel definition layer 12 (e.g., h1 in FIG. 2) is greater than a first predetermined thickness threshold.

In the case that the thickness of the first pixel definition layer 12 is greater than the first preset thickness threshold, it is also possible to make the length and area of the inner side wall of the first pixel opening 121 larger. Thus, in the case that the first pixel definition layer 12 is arranged, the first pixel definition layer 12 is arranged based on the two aspects of the angle r1 and the thickness h1, such that the length and area of the inner side wall of the first pixel opening 121 being sufficiently large is ensured, and the region occupied by the formed first CPM layer 16 is more reasonable.

In some embodiments of the present disclosure, the first predetermined thickness threshold is 2 μm, and the first predetermined thickness threshold can be set based on the actual situation of the display panel. In the case that the region occupied by the first CPM layer 16 is too large, the thickness of the h1 is appropriately increased, such that the length and the area of the inner side wall of the first pixel opening 121 are increased, and the range of the region occupied by the first CPM layer 16 is reduced.

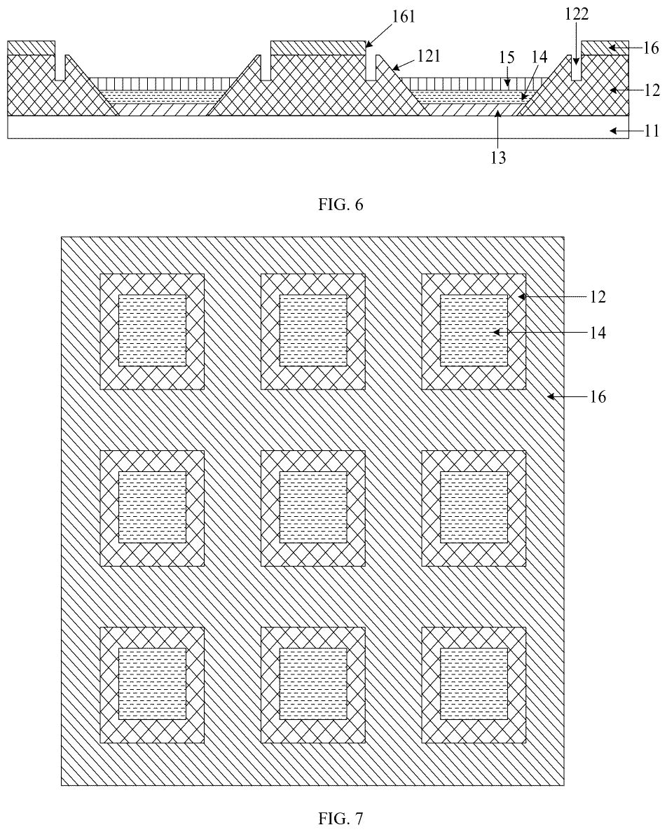

In one possible implementation, in the embodiments of the present disclosure, in order to avoid the occurrence of the problem that the first CPM layer 16 occupies too little region and thus causes the first cathode layer 14 to occupy too much region, in order to avoid the occurrence of the problem that the first CPM layer 16 occupies too much region and thus causes the first cathode layer 14 to occupy too little region (the via m1 of the mask plate m is set too large or the via m1 becomes too large due to the deformation of the mask plate m during the vapor deposition process caused by alternating heat and cold, all of which cause the first CPM layer 16 to occupy a small region), and in order to realize a structure that the first CPM layer 16 is not overlapped with the first cathode layer 14, the first pixel definition layer 12 can be arranged as follows. Referring to FIG. 6, a plurality of first annular partition grooves 122 are disposed on the side, away from the flexible substrate 11, of the first pixel definition layer 12, and the first annular partition grooves 122 surround an outer side of the first pixel opening 121.

The first annular partition groove 122 is disposed on the outer side of each first pixel opening 121. In this way, during evaporation deposition, too much CPM material or too much cathode material can fall into the first annular partition grooves 122. Referring to FIG. 7 (FIG. 7 is a schematic top view structural diagram of the first CPM layer 16, the first cathode layer 14, and the first pixel definition layer 12), it can be seen that the first annular partition grooves 122 blocks the first CPM layer 16 from occupying the first cathode layer 14, and also blocks the first cathode layer 14 from occupying the first CPM layer 16, such that the reasonable regions of the first CPM layer 16 and the first cathode layer 14 are ensured, and the display effect of the display panel and the reliability of the encapsulation are improved.

In the embodiments of the present disclosure, the shape of the first annular partition groove 122 can be any reasonable shape. For example, the shape of the first annular partition groove 122 in the cross-section perpendicular to the flexible substrate 11 is rectangular, and can be other reasonable shapes, which is not limited in the embodiment of the present disclosure.

The groove depth of the first annular partition groove 122 can be greater than ⅓ of the thickness of the first pixel definition layer 12. In this way, it has a better blocking effect.

In one possible implementation, the first CPM layer 16 is a transparent CPM layer. In this way, in the display panel, the first cathode layer 14 is disposed only at a position opposite to the first pixel structure 13, while the other positions are provided with transparent CPMs. Since the transmittance rate of the transparent CPMs is much higher than the transmittance rate of the first cathode layer 14, such a structure can effectively improve the transmittance rate of the display panel.

Moreover, in the case that the region occupied by the first CPM layer 16 is too small and the region occupied by the first cathode layer 14 is too large, the transmittance rate of the display panel is decreased. In the above structure provided to avoid the occupied region of the first CPM layer 16 being too small and the occupied region of the first cathode layer 14 being too large, the first predetermined angle threshold, the first predetermined thickness threshold, and the first annular partition groove 122 all make the occupied region of the first CPM layer 16 and the occupied region of the first cathode layer 14 more reasonable, such that the transmission rate of the display panel is improved.

In one possible implementation, because of the current requirement for UV light trustworthiness of the display panel, the first CPM layer 16 is set to be a UV-resistant transparent CPM layer, in order to improve the UV-resistant performance of the display panel.

In one possible implementation, because the first CPM layer 16 is less compatible with the first pixel definition layer 12, relative sliding is likely to occur between the two in the case that stretching of the display panel is performed, which reduces the reliability of the display panel encapsulation. For this reason, the display panel in the embodiments of the present disclosure is provided with the following structure:

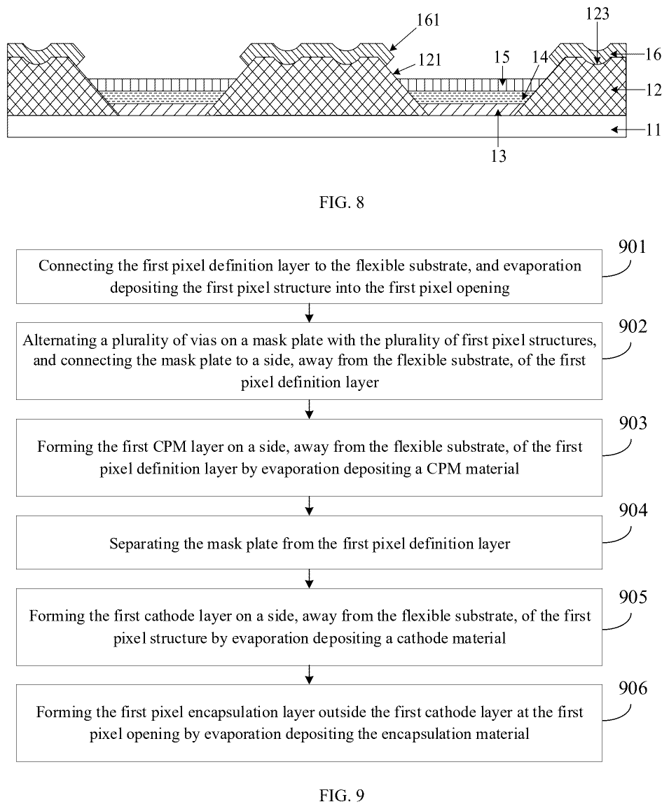

Referring to FIG. 8, a plurality of first arcuate grooves 123 are disposed on a side, away from the flexible substrate 11 of the first pixel definition layer 12, and the first CPM layer 16 is attached to the bottom of the first arcuate grooves 123.

In this way, by providing a plurality of first arcuate grooves 123 on the first pixel definition layer 12, in the case that the CPM material is evaporation deposited, the formed first CPM layer 16 is also attached to the bottom of the first arcuate grooves 123, and the first arcuate grooves 123 can make the first pixel definition layer 12 and the first CPM layer 16 fit more closely together and not prone to relative slipping, such that the reliability of the display panel encapsulation is improved.

The arrangement of the first arcuate groove 123 has the same effect on the connection between the side, away from the first pixel definition layer 12, of the first CPM layer 16 and the other film layers, such that the first CPM layer 16 and the other film layers are not prone to relative sliding, and the reliability of the display panel encapsulation is improved.

Embodiments of the present disclosure provide a method for manufacturing a display panel. The method is applied to any of the above display panels. Referring to FIG. 9, the method includes the following steps.

In 901, the first pixel definition layer 12 is connected to the flexible substrate 11, and the first pixel structure 13 is evaporation deposited into the first pixel opening 121.

In 902, a plurality of vias m1 on a mask plate m are alternated with a plurality of first pixel structures 13, and the mask plate m is connected to a side, away from the flexible substrate 11, of the first pixel definition layer 12.

The mask plate m is connected to the side, away from the flexible substrate 11, of the first pixel definition layer 12 by a magnet, and the plurality of vias m1 on the mask plate m are alternately provided with the plurality of first pixel openings 121 on the first pixel definition layer 12. That is, an orthographic projection of the vias m1 is not overlapped with an orthographic projection of the first pixel openings 121 in the thickness direction along the flexible substrate 11.

In 903, the first CPM layer 16 is formed on a side, away from the flexible substrate 11, of the first pixel definition layer 12 by evaporation depositing the CPM material.

The CPM material is evaporation deposited such that the CPM material can pass through a plurality of vias m1 on the mask plate m and reach the first pixel definition layer 12. Upon passing through the vias m1, the CPM material forms the first CPM layer 16 on the first pixel definition layer 12, such that the formed first CPM layer 16 has a plurality of first cathode openings 161, and each of the first cathode openings 161 is arranged opposite to the position of the first pixel opening 121.

In 904, the mask plate m is separated from the first pixel definition layer 12.

Upon forming the first CPM layer 16, the mask plate m is removed from the first pixel definition layer 12.

In 905, the first cathode layer 14 is formed on a side, away from the flexible substrate 11, of the first pixel structure 13 by evaporation depositing a cathode material.

In the case that the mask plate m is disassembled, the cathode material is evaporation deposited. Because the cathode material is very poorly compatible with the first CPM layer 16, the cathode material cannot be attached to the first CPM layer 16, and the cathode material can only be attached to the first pixel structure 13 at a position opposite to the first cathode openings 161 by the first cathode openings 161 on the first CPM layer 16, such that the corresponding first cathode layer 14 is formed by each of the first cathode openings 161.

In 906, the first pixel encapsulation layer 15 is formed on the outside of the first cathode layer 14 at the first pixel opening 121 by evaporation depositing the encapsulation material.

Upon completing the preparation of the first cathode layer 14, the encapsulation material is evaporation deposited, such that the encapsulation material fills into the first pixel opening 121 and connected to the side, away from the first pixel structure 13, of the first cathode layer 14, and pixel-level encapsulation of the display panel is realized.

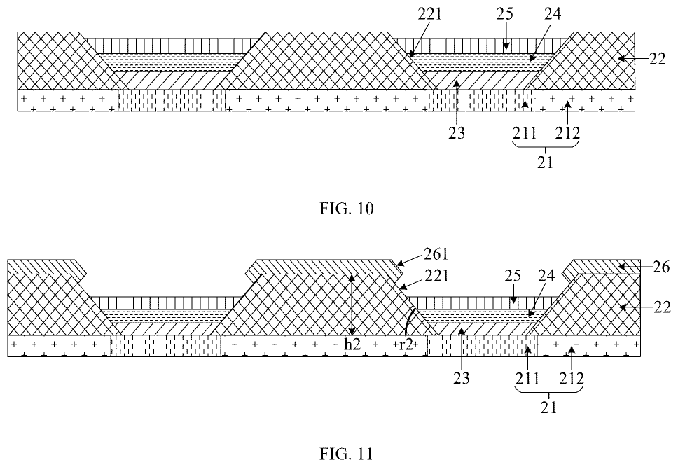

FIG. 10 is a schematic diagram of a structure of a stretchable display panel according to some embodiments of the present disclosure. Referring to FIG. 10, it can be seen that the stretchable display panel includes a substrate 21, a second pixel definition layer 22, a plurality of second pixel structures 23, a plurality of second cathode layers 24, and a plurality of second pixel encapsulation layers 25.

The substrate 21 is mainly configured to support the second pixel structures 23, and its material is plastic or the like. The substrate 21 include a plurality of pixel islands 211 and a plurality of line bridges 212. The pixel islands 211 are connected to the adjacent line bridges 212, the adjacent pixel islands 211 are electrically connected to each other by lines on the line bridges 212 therebetween, and the line bridges 212 is capable of realizing a stretching property of the stretchable display panel.

The second pixel definition layer 22 is attached to the substrate 21 and the two are provided in a stack. The second pixel definition layer 22 is configured to partition a position for a plurality of second pixel structures 23 on the substrate 21. The second pixel definition layer 22 has a plurality of second pixel openings 221, the plurality of second pixel openings 221 are uniformly distributed on the second pixel definition layer 22 and correspond to the pixel islands 211 in terms of position.

The shape of the second pixel openings 221 is rectangular, rhombic, etc., which is not limited in the embodiments of the present disclosure.

The plurality of second pixel structures 23 are respectively disposed in the plurality of second pixel openings 221 and attached to the pixel islands 211. The second cathode layer 24 is disposed within the second pixel openings 221, on a side, away from the second pixel definition layer 22, of the second pixel structures 23, and attached to the second pixel structures 23. Each of the second pixel structures 23 is opposite and attached to one second cathode layer 24. By applying pressure at both ends of the second pixel structures 23 and the second cathode layer 24, the second pixel structures 23 are caused to emit light, such that the display panel is caused to display an image.

There are various methods for realizing the plurality of second cathode layers 24. Exemplarily, cathode patterning can be realized by CPM material, cathode patterning can be realized by laser etching, or other possible methods, which are not limited in the embodiments of the present disclosure.

The material of the second cathode layer 24 is a metal material or a synthetic metal material. For example, it may be ITO, MgAg, Ag, Al, Mg, and the like, which is not limited in the embodiments of the present disclosure.

The second pixel encapsulation layer 25 is disposed at the second pixel opening 221, outside of the second cathode layer 24, and seals the second pixel opening 221. Each second pixel encapsulation layer 25 encapsulates one second pixel structure 23 and a corresponding second cathode layer 24.

In this way, a corresponding second cathode layer 24 is provided for each second pixel structure 23, thereby facilitating the realization of pixel-level encapsulation of the stretchable display panel, avoiding the occurrence of encapsulation failure caused by the use of undercut structures, and improving the stability of the encapsulation.

In one possible implementation, the patterning of this plurality of second cathode layers 24 can be achieved by CPM, referring to FIG. 11, and the structural arrangement can be as follows.

The stretchable display panel further includes a second CPM layer 26, and the second CPM layer 26 is disposed on a side, away from the substrate 21, of the second pixel definition layer 22 and attached to the second pixel definition layer 22. The second CPM layer 26 has a plurality of second cathode openings 261, and the second cathode openings 261 correspond to the second pixel structures 23 in terms of position. The second CPM layer 26 is used for cathode patterning process to acquire a plurality of second cathode layers 24, and the position of each of the second cathode layers 24 is opposite to the position of one of the second pixel structures 23.

The material of the second CPM layer 26 is a high-fluorine-containing compound, which is less compatible with the cathode material.

In preparing the stretchable display panel by the CPM material, the second pixel definition layer 22 needs to be connected to one side of the substrate 21, and then a plurality of second pixel structures 23 need to be disposed within the plurality of second pixel openings 221 of the second pixel definition layer 22 and connected to the substrate 21, and then, the second CPM layer 26 needs to be evaporation deposited on the side, away from the substrate 21, of the second pixel definition layer 22. The formed second CPM layer 26 has a plurality of second cathode openings 261, and the positions of these plurality of second cathode openings 261 correspond to the positions of the second pixel structures 23, such that the regions in the second pixel definition layer 22 other than the second pixel structures 23 can be provided with CPM material.

In the case that the second CPM layer 26 is formed, the cathode material is evaporation deposited on a side, away from the second pixel definition layer 22, of the second CPM layer 26. Because of the poor compatibility between the cathode material and the CPM material, it is difficult for the cathode material to be attached to the CPM material, and the cathode material is attached, through a plurality of the second cathode openings 261 on the second CPM layer 26, to the second pixel structure 23 corresponding to the second cathode openings 261 in terms of position, such that each of the second pixel structures 23 is attached to a corresponding second cathode layer 24.

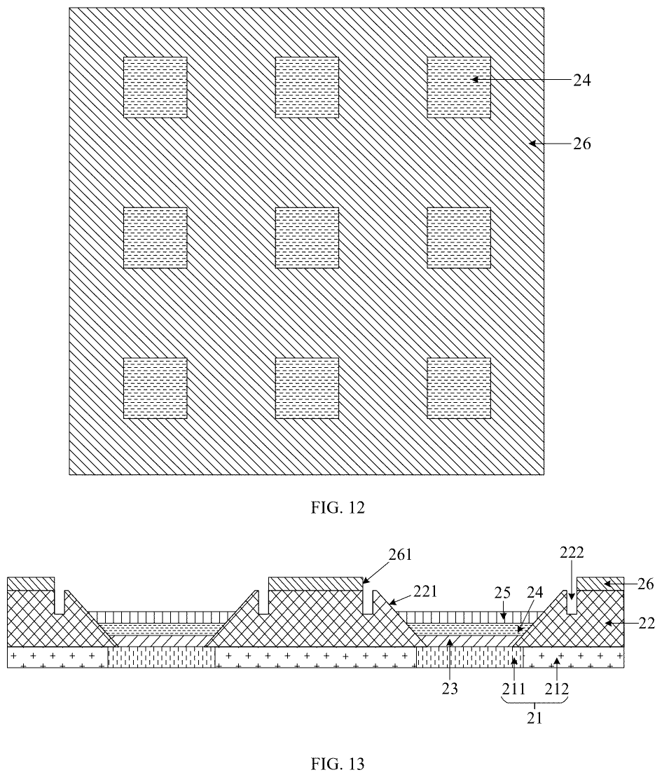

In this way, the stretchable display panel can be formed as shown in FIG. 12. FIG. 12 is a schematic top view structural diagram of the second CPM layer 26 and the plurality of second cathode layers 24. In conjunction with FIGS. 11 and 12, it can be seen that, in the stretchable display panel, the second cathode layer 24 is provided only at a position opposite to the second pixel structure 23, and the CPM material is provided at other positions, and such a structure facilitates pixel-level encapsulation and improves the reliability of the encapsulation of the stretchable display panel.

In one possible implementation, in the stretchable display panel provided in the embodiments of the present disclosure, the orthographic projection of the second CPM layer 26 is not overlapped with the orthographic projection of the second cathode layer 24 along the thickness direction of the substrate 21.

In this way, a reasonable space can be allocated for each of the second CPM layer 26 and the plurality of second cathode layers 24, such that the occurrence of the problem that the second CPM layer 26 occupies too much region and causes the second cathode layer 24 to occupy too little region is avoided, and the occurrence of the problem that the second CPM layer 26 occupies too little region and thereby causes the second cathode layer 24 to occupy too much region is avoided, thereby improving the display effect of the stretchable display panel, and improving the reliability of the pixel-level encapsulation of the stretchable display panel.

In one possible implementation, the shape of the second pixel opening 221 is a square prism shape. That is, the angle (e.g., angle r2 in FIG. 11) between the inner side wall of the second pixel opening 221 and the side, close to the substrate 21, of the second pixel definition layer 22 is less than 90 degrees, and correspondingly, the angle between the inner side wall of the second pixel opening 221 and the side, away from the substrate 21, of the second pixel definition layer 22 is greater than 90 degrees. In this way, each of the inner side walls of the second pixel openings 221 forms a sloping surface, which facilitates the climbing of the layer structure and reduces the risk of breakage of the layer structure in the case that the second pixel structure 23 and the second cathode layer 24 are evaporation deposited.

In one possible implementation, in the embodiments of the present disclosure, in order to avoid the occurrence of the problem that the second CPM layer 26 occupies too much region and thus the second cathode layer 24 occupies too little region, and in order to realize a structure in which the second CPM layer 26 is not overlapped with the second cathode layer 24, the second pixel definition layer 22 is arranged in the following manner: the angle (e.g., the angle r2 in FIG. 11) between the inner side wall of the second pixel opening 221 and the side, close to the substrate 21, of the second pixel definition layer 22 is less than a first predetermined angle threshold, and the first predetermined angle threshold can be less than 90 degrees.

Similar to the process of manufacturing the display panel described above, in the process of manufacturing the stretchable display panel, prior to evaporation depositing the CPM material 162, it is necessary to install the mask plate m on the side, away from the substrate 21, of the second pixel definition layer 22, and connect the mask plate m to the second pixel definition layer 22 by magnets. The mask plate m has a plurality of vias m1 on the mask plate m, and it is necessary to alternate the plurality of second pixel openings 221 with the plurality of vias m1. That is, in the thickness direction along the substrate 21, the orthographic projections of the vias m1 is not overlapped with the orthographic projections of the second pixel openings 221. In the case that the mask plate m is installed, the CPM material 162 can be evaporation deposited to pass through the vias m1 to form the second pixel definition layer 22 having the second cathode openings 261 at the second pixel definition layer 22 corresponding to the vias m1 in terms of position.

Then, the cathode material 141 is evaporation deposited, and the cathode material 141 cannot be attached to the second CPM layer 26. The cathode material formed by evaporation deposition is partitioned by the second CPM layer 26 into a plurality of unconnected second cathode layers 24 that are each connected to a second pixel structure 23.

During the above manufacturing process, a circle of CPM on the outside of the via m1 is formed due to a gap between the mask plate m and the second pixel definition layer 22, and the circle of shadow increases the region occupied by the second CPM layer 26.

In order to avoid the occurrence of the above problem that the second CPM layer 26 increases due to the shadow and thus occupies the region of the second cathode layer 24, the angle r2 is set to be less than a first predetermined angle threshold, and the length and area of the inner side wall of the second pixel opening 221 is increased, such that the shadow is formed at the position, away from the second pixel structure 23, of the inner side wall of the second pixel opening 221, and the formed second CPM layer 26 does not occupy the position occupied by the second cathode layer 24, ensuring a reasonable region arrangement of the second cathode layer 24, and the second cathode layer is fully contacted with the second pixel structure 23, which improves the display effect of the stretchable display panel and improves the reliability of the encapsulation.

In the embodiments of the present disclosure, the first predetermined angle threshold is 60 degrees, and, the first predetermined angle threshold can be set based on the actual situation of the stretchable display panel. In the case that the region occupied by the second CPM layer 26 is too large, the angle r2 can be appropriately reduced, such that the length and area of the inner side wall of the second pixel opening 221 are increased, and the range of the region occupied by the second CPM layer 26 is reduced.

In one possible implementation, in the case that the adjustment of the angle r2 cannot satisfy the requirement of the region occupied by the second CPM layer 26, the following arrangement can also be made on the premise of the above arrangement of the angle r2. The thickness of the second pixel definition layer 22 (e.g., h2 in FIG. 11) is greater than the first predetermined thickness threshold.

In the case that the thickness of the second pixel definition layer 22 is greater than the first predetermined thickness threshold, it is also possible to make the length and area of the inner side wall of the second pixel opening 221 larger. Thus, in the case that the second pixel definition layer 22 is arranged, the second pixel definition layer 22 is arranged based on the two aspects of the angle r2 and the thickness h2, such that the length and area of the inner side wall of the second pixel opening 221 being sufficiently large is ensured, and the region occupied by the formed second CPM layer 26 is more reasonable.

In some embodiments of the present disclosure, the first predetermined thickness threshold is 2 μm, and the first predetermined thickness threshold can be set based on the actual situation of the stretchable display panel. In the case that the region occupied by the second CPM layer 26 is too large, the thickness of the h2 is appropriately increased, such that the length and the area of the inner side wall of the second pixel opening 221 is increased, and the range of the region occupied by the second CPM layer 26 is reduced.

In one possible implementation, in the embodiments of the present disclosure, in order to realize a structure that the second CPM layer 26 is not overlapped with the second cathode layer 24, the second pixel definition layer 22 is arranged as follows. Referring to FIG. 13, a plurality of second annular partition grooves 222 are disposed on the side, away from the substrate 21, of the second pixel definition layer 22, and the second annular partition grooves 222 surround an outer side of the second pixel opening 221.

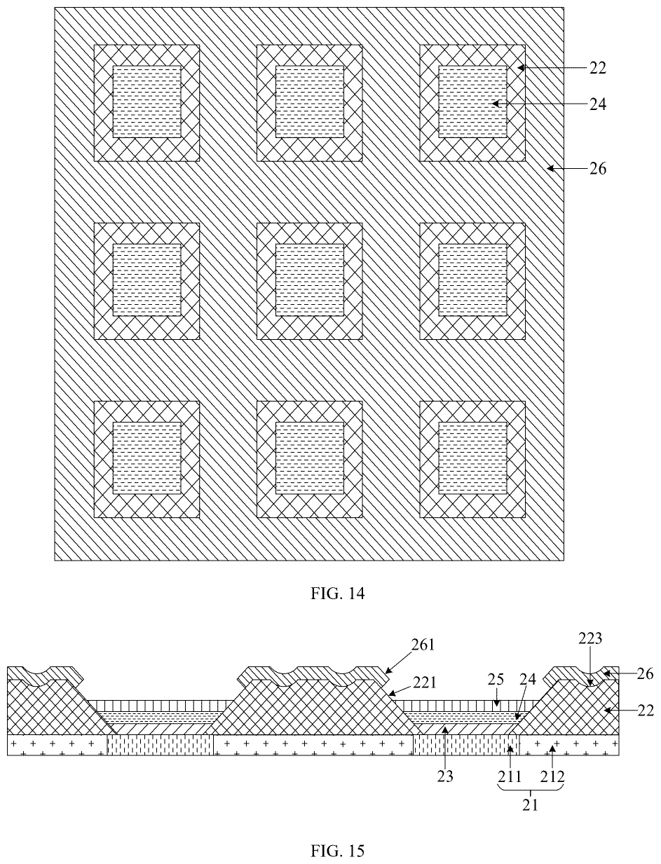

The second annular partition groove 222 is disposed on the outer side of each second pixel opening 221. In this way, during evaporation deposition, too much CPM material or too much cathode material can fall into the second annular partition groove 222. Referring to FIG. 14 (FIG. 14 is a schematic top view structural diagram of the second CPM layer 26, the second cathode layer 24, and the second pixel definition layer 22), it can be seen that the second annular partition groove 222 blocks the second CPM layer 26 from occupying the second cathode layer 24, and also blocks the second cathode layer 24 from occupying the second CPM layer 26, such that the reasonable regions of the second CPM layer 26 and the second cathode layer 24 are ensured, and the display effect of the stretchable display panel and the reliability of the encapsulation are improved.

In the embodiments of the present disclosure, the shape of the second annular partition groove 222 can be any reasonable shape. For example, the shape of the second annular partition groove 222 in the cross-section perpendicular to the substrate 21 is rectangular, and can be other reasonable shapes, which is not limited in the embodiment of the present disclosure.

The groove depth of the second annular partition groove 222 can be greater than ⅓ of the thickness of the second pixel definition layer 22. In this way, it has a better blocking effect.

In one possible implementation, the second CPM layer 26 is a transparent CPM layer. In this way, in the stretchable display panel, the second cathode layer 24 is disposed only at a position opposite to the second pixel structure 23, while the other positions are provided with transparent CPM. Since the transmittance rate of the transparent CPM is much higher than the transmittance rate of the second cathode layer 24, such a structure can effectively improve the transmittance rate of the stretchable display panel.

Moreover, in the case that the region occupied by the second CPM layer 26 is too small and the region occupied by the second cathode layer 24 is too large, the transmittance rate of the stretchable display panel is decreased. In the above structure provided to avoid the occupied region of the second CPM layer 26 being too small and the occupied region of the second cathode layer 24 being too large, the first predetermined angle threshold, the first predetermined thickness threshold, and the second annular partition groove 222 all make the occupied region of the second CPM layer 26 and the occupied region of the second cathode layer 24 more reasonable, such that the transmittance rate of the stretchable display panel is improved.

In one possible implementation, because of the current requirement for UV light trustworthiness of the display panel, the second CPM layer 26 is set to be a UV-resistant transparent CPM layer to improve the UV-resistant performance of the display panel.

In one possible implementation, because the second CPM layer 26 is less compatible with the second pixel definition layer 22, relative sliding is likely to occur between the two in the case that stretching of the stretchable display panel is performed, which reduces the reliability of the stretchable display panel encapsulation. For this reason, the stretchable display panel in the embodiments of the present disclosure is provided with the following structure.

Referring to FIG. 15, a plurality of second arcuate grooves 223 are disposed on a side, away from the substrate 21, of the second pixel definition layer 22, and the second CPM layer 26 is attached to the bottom of the second arcuate grooves 223.

In this way, by providing the plurality of second arcuate grooves 223 on the second pixel definition layer 22, in the case that the CPM material is evaporation deposited, the formed second CPM layer 26 is also attached to the bottom of the second arcuate grooves 223, and the second arcuate grooves 223 can make the second pixel definition layer 22 and the second CPM layer 26 more closely together and not prone to relative slipping, such that the reliability of the stretchable display panel encapsulation is improved.

The arrangement of the second arcuate groove 223 has the same effect on the connection between the side, away from the second pixel definition layer 22, of the second CPM layer 26 and the other film layers, such that the second CPM layer 26 and the other film layers are not prone to relative sliding, and the reliability of the stretchable display panel encapsulation is improved.

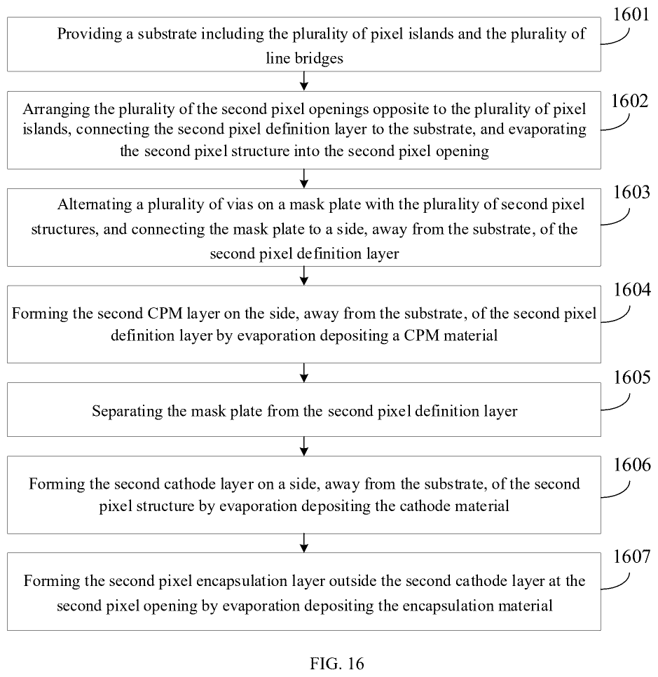

Embodiments of the present disclosure provide a method for manufacturing a stretchable display panel. The method is applied to any of the above stretchable display panels. Referring to FIG. 16, the method includes the following steps.

In 1601, a substrate 21 including a plurality of pixel islands 211 and a plurality of line bridges 212 is provided.

In 1602, a plurality of second pixel openings 221 directly is arranged opposite to the plurality of pixel islands 211, and the second pixel definition layer 22 is connected to the substrate 21, and a second pixel structure 23 is evaporation deposited into the second pixel openings 221.

1603, the plurality of vias m1 on the mask plate m is alternated with the plurality of second pixel structures 23, and the mask plate m is connected to a side, away from the substrate 21, of the second pixel definition layer 22.

The mask plate m is connected to the side, away from the substrate 21, of the second pixel definition layer 22 by a magnet, and the plurality of vias m1 on the mask plate m are alternately provided with the plurality of second pixel openings 221 on the second pixel definition layer 22. That is, an orthographic projection of the vias m1 is not overlapped with an orthographic projection of the second pixel openings 221 in the thickness direction along the substrate 21.

In 1604, the second CPM layer 26 is formed on a side, away from the substrate 21, of the second pixel definition layer 22 by evaporation depositing the CPM material.

The CPM material is evaporation deposited such that the CPM material can pass through a plurality of vias m1 on the mask plate m and reach the second pixel definition layer 22. Upon passing through the vias m1, the CPM material forms the second CPM layer 26 on the second pixel definition layer 22, such that the formed second CPM layer 26 has a plurality of second cathode openings 261, and each of the second cathode openings 261 is arranged opposite to the position of the second pixel opening.

In 1605, the mask plate m is separated from the second pixel definition layer 22.

Upon forming the second CPM layer 26, the mask plate m is removed from the second pixel definition layer 22.

In 1606, the second cathode layer 24 is formed on a side, away from the substrate 21, of the second pixel structure 23 by evaporation depositing the cathode material.

After the mask plate m is removed, the cathode material can be evaporation deposited, and since the cathode material is very poorly compatible with the second CPM layer 26, the cathode material cannot be attached to the second CPM layer 26, but can only be attached to the second pixel structure 23 at a position directly opposite the second cathode openings 261 through the second cathode openings 261 on the second CPM layer 26, so that through each second cathode opening 261 forming a corresponding second cathode layer 24.

In 1607, the second pixel encapsulation layer 25 is formed on the outside of the second cathode layer 24 at the second pixel opening 221 by evaporation depositing the encapsulation material.

Upon completing the preparation of the second cathode layer 24, the encapsulation material is evaporation deposited, such that the encapsulation material fills into the second pixel opening 221 and connected to the side, away from the second pixel structure 23, of the second cathode layer 24, and the pixel-level encapsulation of the stretchable display panel is realized.

Embodiments of the present disclosure provide a display device. The display device includes any one of the display panels or any one of the stretchable display panels as described in the above embodiments, which improves the transmittance rate of the display panel and improves the display effect of the display device.

Optionally, the display device may be an OLED display device, a liquid crystal display device, an electronic paper, a cell phone, a tablet computer, a television, a monitor, a laptop computer, a digital photo frame, or a navigator, and any other product or component with a display function, which is not limited in the embodiments of the present disclosure.

Exemplarily, in the case that the display device is an OLED display device, the structure of the first pixel structure 13 thereof can be as follows. The first pixel structure 13 includes an anode layer and an EL layer, the anode layer is disposed within the first pixel opening 121 and attached to the flexible substrate 11. The EL layer is disposed within the first pixel opening 121 on a side, away from the flexible substrate 11, of the anode layer and attached to the anode layer. The first cathode layer 14 is disposed on the side, away from the anode layer, of the EL layer and attached to the EL layer.

In the case that a voltage is applied to the anode layer and the first cathode layer 14, the anode layer and the first cathode layer 14 inject holes and electrons into the EL layer. The holes and electrons meet in the EL layer and generate energy, and ultimately the energy is released in the form of luminescence, thereby realizing luminescence of the pixel structure.

The EL layer includes an electron transmission layer, a hole blocking layer, a light emitting layer, and a hole transmission layer, which are provided in a sequential stacked configuration. The electron transmission layer is disposed on a side, close to the flexible substrate 11, of the first cathode layer 14 and attached to the first cathode layer 14. The hole transmission layer is disposed on a side, away from the flexible substrate 11, of the anode layer and attached to the anode layer.

The term “at least one” in this application means one or more, and the term “more than one” in this application means two or more.

In this application, the terms “first” and “second” are used to distinguish the same or similar items having essentially the same function and function, and it should be understood that “first” and “second” are not the same as each other. It should be understood that there is no logical or temporal dependence between “first” and “second,” nor is there any limitation on the number or order of performance. It should also be understood that while the following description uses the terms “first” and “second”, or the like. to describe various structures, these structures should not be limited by terminology. These terms are only used to distinguish one structure from another. For example, without departing from the scope of the various examples, the first portion may be referred to as the second portion, and similarly, the second portion may be referred to as the first portion.

Described above are only exemplary embodiments of the present application, but the scope of protection of the present application is not limited thereto. Any person skilled in the art can readily envisage various equivalent modifications or substitutions within the scope of the technology disclosed in the present application, which shall be covered by the scope of protection of the present application. Therefore, the scope of protection of this application shall be subject to the scope of protection of the claims.

1. A display panel, comprising a flexible substrate, a first pixel definition layer, a plurality of first pixel structures, a plurality of first cathode layers, and a plurality of first pixel encapsulation layers; wherein
the first pixel definition layer is attached to the flexible substrate and a plurality of first pixel openings are defined in the first pixel definition layer;
the plurality of first pixel structures are respectively disposed in the plurality of first pixel openings and attached to the flexible substrate;
each of the plurality of first cathode layers is disposed in each of the plurality of first pixel openings and attached to each of the plurality of first pixel structures; and
each of the plurality of first pixel encapsulation layers is disposed outside each of the plurality of first cathode layers at each of the plurality of first pixel openings and seals the first pixel opening.

2. The display panel according to claim 1, further comprising: a first CPM layer;
wherein the first CPM layer is disposed on a side, away from the flexible substrate, of the first pixel definition layer and attached to the first pixel definition layer; and
a plurality of first cathode openings are arranged in the first CPM layer, wherein the plurality of first cathode openings correspond to the plurality of first pixel structures in terms of position.

3. The display panel according to claim 2, wherein an orthographic projection of the first CPM layer is not overlapped with an orthographic projection of each of the plurality of first cathode layers along a thickness direction of the flexible substrate (11).

4. The display panel according to claim 3, wherein an angle between an inner side wall of the first pixel opening and a side, close to the flexible substrate, of the first pixel definition layer is less than a first predetermined angle threshold.

5. The display panel according to claim 4, wherein a thickness of the first pixel definition layer is greater than a first predetermined thickness threshold.

6. The display panel according to claim 3, wherein a plurality of first annular partition grooves are disposed in a side, away from the flexible substrate, of the first pixel definition layer, wherein the first annular partition grooves surround an outer side of the first pixel opening.

7. The display panel according to claim 2, wherein the first CPM layer is a transparent CPM layer.

8. The display panel according to claim 7, wherein the first CPM layer is a UV resistant transparent CPM layer.

9. The display panel according to claim 2, wherein a plurality of first arcuate grooves are disposed in a side, away from the flexible substrate, of the first pixel definition layer; and
the first CPM layer is attached to bottoms of the plurality of first arcuate grooves.

10. A stretchable display panel, comprising: a substrate, a second pixel definition layer, a plurality of second pixel structures, a plurality of second cathode layers, and a plurality of second pixel encapsulation layers; wherein
the substrate comprises a plurality of pixel islands and a plurality of line bridges, wherein each of the plurality of the pixel islands is connected to adjacent two of the plurality of line bridges;
the second pixel definition layer is attached to the substrate, and a plurality of second pixel openings are defined in the second pixel definition layer, wherein each of the plurality of second pixel openings corresponds to each of the plurality of pixel islands in terms of position;
the plurality of second pixel structures are respectively disposed in the plurality of second pixel openings and attached to the pixel island;
each of the plurality of second cathode layers is disposed in each of the plurality of second pixel opening and attached to each of the plurality of second pixel structures; and
each of the plurality of second pixel encapsulation layers is disposed outside each of the plurality of second cathode layers at each of the plurality of second pixel openings and seals the second pixel opening.

11. The stretchable display panel according to claim 10, further comprising: a second CPM layer; wherein
the second CPM layer is disposed on a side, away from the substrate, of the second pixel definition layer and attached to the second pixel definition layer; and
a plurality of second cathode openings are defined in the second CPM layer, wherein each of the plurality of second cathode openings corresponds to each of the plurality of second pixel structures in terms of position.

12. The stretchable display panel according to claim 11, wherein an orthographic projection of the second CPM layer is not overlapped with an orthographic projection of each of the plurality of second cathode layers along a thickness direction of the substrate.

13. The stretchable display panel according to claim 12, wherein an angle between an inner side wall of the second pixel opening and a side, close to the substrate, of the second pixel definition layer is less than a first predetermined angle threshold.

14. The stretchable display panel according to claim 13, wherein a thickness of the second pixel definition layer is greater than a second predetermined thickness threshold.

15. The stretchable display panel according to claim 12, wherein a plurality of second annular partition grooves are disposed in a side, away from the substrate, of the second pixel definition layer, wherein the second annular partition grooves surround an outer side of the second pixel opening.

16. The stretchable display panel according to claim 11, wherein the second CPM layer is a UV resistant transparent CPM layer.

17. The stretchable display panel according to claim 11, wherein a plurality of second arcuate grooves are defined in a side, away from the substrate, of the second pixel definition layer; and
the second CPM layer is attached to bottoms of the second arcuate grooves.

18. A method for manufacturing a display panel, wherein the method is applied to the display panel as defined in claim 2, and the method comprises:
connecting the first pixel definition layer to the flexible substrate, and evaporation depositing the first pixel structure into the first pixel opening;
alternating a plurality of vias on a mask plate with the plurality of first pixel structures, and connecting the mask plate to a side, away from the flexible substrate, of the first pixel definition layer;
forming the first CPM layer on a side, away from the flexible substrate, of the first pixel definition layer by evaporation depositing a CPM material;
separating the mask plate from the first pixel definition layer;
forming the first cathode layer on a side, away from the flexible substrate, of the first pixel structure by evaporation depositing a cathode material; and
forming the first pixel encapsulation layer outside the first cathode layer at the first pixel opening by evaporation depositing the encapsulation material.

19. A method for manufacturing a display panel, wherein the method is applicable to the stretchable display panel as defined in claim 11, and the method comprises:
providing a substrate comprising the plurality of pixel islands and the plurality of line bridges;
arranging the plurality of the second pixel openings opposite to the plurality of pixel islands, connecting the second pixel definition layer to the substrate, and evaporation depositing the second pixel structure into the second pixel opening;
alternating a plurality of vias on a mask plate with the plurality of second pixel structures, and connecting the mask plate to a side, away from the substrate, of the second pixel definition layer;
forming the second CPM layer on the side, away from the substrate, of the second pixel definition layer by evaporation depositing a CPM material;
separating the mask plate from the second pixel definition layer;
forming the second cathode layer on a side, away from the substrate, of the second pixel structure by evaporation depositing the cathode material; and
forming the second pixel encapsulating layer outside the second cathode layer at the second pixel opening by evaporation depositing the encapsulation material.

20. A display device, comprising: a display panel a stretchable display panel; wherein
the display panel comprises a flexible substrate, a first pixel definition layer, a plurality of first pixel structures, a plurality of first cathode layers, and a plurality of first pixel encapsulation layers; wherein
the first pixel definition layer is attached to the flexible substrate and a plurality of first pixel openings are defined in the first pixel definition layer;
the plurality of first pixel structures are respectively disposed in the plurality of first pixel openings and attached to the flexible substrate;
each of the plurality of first cathode layers is disposed in each of the plurality of first pixel openings and attached to each of the plurality of first pixel structures; and
each of the plurality of first pixel encapsulation layers is disposed outside each of the plurality of first cathode layers at each of the plurality of first pixel openings and seals the first pixel opening; and
the stretchable display panel comprises a substrate, a second pixel definition layer, a plurality of second pixel structures, a plurality of second cathode layers, and a plurality of second pixel encapsulation layers; wherein
the substrate comprises a plurality of pixel islands and a plurality of line bridges, wherein each of the plurality of the pixel islands is connected to adjacent two of the plurality of line bridges;
the second pixel definition layer is attached to the substrate, and a plurality of second pixel openings are defined in the second pixel definition layer, wherein each of the plurality of second pixel openings corresponds to each of the plurality of pixel islands in terms of position;
the plurality of second pixel structures are respectively disposed in the plurality of second pixel openings and attached to the pixel island;
each of the plurality of second cathode layers is disposed in each of the plurality of second pixel opening and attached to each of the plurality of second pixel structures; and
each of the plurality of second pixel encapsulation lavers is disposed outside each of the plurality of second cathode lavers at each of the plurality of second pixel openings and seals the second pixel opening.
